(19) United States
(12) Patent Application Publication
(10) Pub. No.: US 2012/0073661 A1
(43) Pub. Date: Mar. 29, 2012

(54) PHOTOELECTRIC CONVERSION ELEMENT AND SOLAR CELL

(75) Inventors: Kenichi ONAKA, Tokyo (JP); Kazuya ISOBE, Tokyo (JP); Hideya MIWA, Tokyo (JP); Kazukuni NISHIMURA, Tokyo (JP)

(73) Assignee: KONICA MINOLTA BUSINESS TECHNOLOGIES, INC., Tokyo (JP)

(21) Appl. No.: 13/237,285

(22) Filed: Sep. 20, 2011

(30) Foreign Application Priority Data
Sep. 25, 2010 (JP) 2010-214597

(51) Int. Cl. H01L 51/46

(52) U.S. Cl. 136/263

(57) ABSTRACT

Provided is a photoelectric conversion element composed of a highly durable sensitizing dye, exhibiting high photoelectric conversion efficiency, and also a solar cell fitted with the photoelectric conversion element. A photoelectric conversion element comprising a substrate provided thereon a first electrode, a photoelectric conversion layer having a semiconductor and a sensitizing dye, a charge transporting layer and a second electrode, wherein the photoelectric conversion layer comprising a compound represented by Formula (1), Formula (1): R₁—X—R₂—B, wherein R₁ represents C(R₃)(R₄)(R₅), R₃, R₄, and R₅ represents a hydrogen atom, a methyl group or an ethyl group, provided that R₃, R₄, and R₅ are not simultaneously a hydrogen atom, X represents a substituted or non-substituted cyclohexane ring, a substituted or non-substituted benzene ring, or a substituted or non-substituted pyrimidine ring, R₂ represents a methylene group, an ethylene group, or a single bond, B represents a carboxyl group, a sulfa group or a phosphono group.

This application is based on Japanese Patent Application No. 2010-214597 filed on Sep. 25, 2010, in Japanese Patent Office, the entire content of which is hereby incorporated by reference.

### TECHNICAL FIELD

The present invention relates to a photoelectric conversion element, and specifically to a photoelectric conversion element and a solar cell exhibiting high photoelectric conversion efficiency and durability for a light irradiation.

### BACKGROUND OF THE INVENTION

In recent years, application of infinite solar light producing no harmful substances has been actively studied. Inorganic type solar cells such as single crystalline silicon, polycrystalline silicon, amorphous silicon, and cadmium telluride and indium copper selenide for residential use are provided as those presently available in practical use as a clean energy source in application of solar light.

However, as drawbacks of these inorganic type solar cells, in the case of the silicon type, not only extremely high purity is required, but also the complicated purification process includes many steps at high production coat.

On the other hand, many solar cells employing an organic material have also been proposed. Examples of the organic solar cell include a Schottky type photoelectric conversion element in which a p-type organic semiconductor and metal having a small work function are joined, and a heterojunction type photoelectric conversion element in which a p-type organic semiconductor and an n-type inorganic semiconductor or a p-type organic semiconductor and an electron acceptable organic compound are joined. The utilized organic semiconductors are synthesized dyes or pigments such as chlorophyll, perylene and so forth, conductive polymers such as polyacetylene and so forth, and the composite material thereof. Such the material to be used as the cell material is thin-layered by a vacuum evaporation method, a casting method, a dipping method or the like. The organic materials have advantages of low cost and easy production of large area, but there is a problem such as a low conversion efficiency of 1% or less together with insufficient durability.

In such the situation, a solar cell exhibiting favorable properties has been reported by Dr. Gratzel et al. in Switzerland, cf. Non-patent document 1 for example. The proposed cell is a dye sensitizing type solar cell, which comprises a first electrode, a functional electrode, and a second electrode in this order, and an electrolyte solution is filled between the functional electrode and the second electrode. Herein, a porous semiconductor such as titanium oxide spectrally absorbed by a dye is provided as the functional electrode.

However, since the dye absorbed to the porous semiconductor cannot completely cover the porous semiconductor, a charge transporting layer contacts with the porous semiconductor without a dye layer and results in occurring a partial short-circuit, whereby it causes that the photoelectric conversion efficiency does not increase.

In order to prevent a reverse electron transfer by short-circuit and to improve a time degradation of the photoelectric conversion efficiency, a method is proposed in which after absorbing a dye to a porous semiconductor, an additive having a functional group absorbable to the porous semiconductor (such as imidazolyl group, carboxyl group, sulfonic group) is further absorbed, whereby the additive covers a surface of porous semiconductor where the dye is not absorbed (referred to Patent Document 1).

In above Patent Document 1, an example is described in which after absorbing a dye to a surface of porous semiconductor, tert-butyl pyridine is further absorbed as the above additive, whereby results in improving a time degradation of the photoelectric conversion efficiency, as well as preventing a reverse electron transfer.

In Patent Document 1, described is an enhancement of durability under natural aging, however, there is no description with respect to durability after continuous light irradiation. Our evaluation of durability after continuous light irradiation shows unsatisfactory results. Further, an initial characteristic of photoelectric conversion efficiency by preventing a reverse electron transfer (preventing by short-circuit) is still insufficient and significant improvement is desired.

### PRIOR TECHNICAL DOCUMENT

### Patent Document

Patent Document 1: Unexamined Japanese Patent Application (hereinafter referred to as JP-A) No. 2006-134631

### Non-Patent Document

Non-patent Document 1: B. O' Regan and M. Gratzel, Nature, 353, 737 (1991)

### SUMMARY OF THE INVENTION

An object of the present invention is to provide a photoelectric conversion element and a solar cell exhibiting high photoelectric conversion efficiency and durability for a light irradiation.

The above object of the present invention is accomplished by any of the following structures.

The reason of low photoelectric conversion efficiency in photoelectric conversion element employing a solid charge transporting layer is realized to be caused by reverse electron transfer from charge transporting layer to semiconductor. In order to prevent a reverse electron transfer, the inventors of the present invention conducted diligent investigation of a method for preventing short-circuit by contacting charge transporting layer with surface of semiconductor. As a result, by comprising a compound represented by Formula (I) in the photoelectric conversion layer for protecting bared surface of the semiconductor, whereby recombination is prevented between electron in semiconductor and hole of charge transporting layer and excellent photoelectric conversion efficiency was achieved.

1. A photoelectric conversion element comprising a substrate provided thereon a first electrode, a photoelectric conversion layer having a semiconductor and a sensitizing dye, a charge transporting layer and a second electrode, wherein the photoelectric conversion layer comprising a compound represented by Formula (1),

R₁—X—R₂—B, Formula (1)

wherein R₁ represents C(R₃)(R₄)(R₅), R₃, R₄, and R₅ respectively represents a hydrogen atom, a methyl group or an ethyl group, provided that R₃, R₄, and R₅ are not simultaneously a hydrogen atom, X represents a substituted or non-substituted cyclohexane ring, a substituted or non-substituted benzene ring, or a substituted or non-substituted pyrimidine ring, R₂ represents a methylene group, an ethylene group, or a single bond, B represents a carboxyl group, a sulfo group or a phosphono group.

Each component in R₁—X—R₂—B in Formula (I) is considered to be effective in the following function.

R₁: bulky structure which prevents a charge transporting material from approaching to a surface of the semiconductor,

X: relatively rigid ring structure which assist the molecule to closely cover the surface,

R₂: part which acts as spacer, for being easy to move and absorb group for absorption, and

B: group for absorption.

Specifically, the compound represented by Formula (1) in the present invention is considered to be a co-absorbed compound having an ability of absorbing to the semiconductor together with dye. For an ability of absorbing to the semiconductor, it comprises any one of a carboxyl group, a sulfo group or a phosphono group. For preventing a charge transporting material from approaching to a surface of the semiconductor as well as extensively covering the semiconductor surface, it comprises a substituted or non-substituted cyclohexane ring, a substituted or non-substituted benzene ring, or a substituted or non-substituted pyrimidine ring which is ring structure having bulky substituent. Further, for being easy to absorb to the semiconductor surface, it may comprise a spacer structure having a mobile group for absorption. As for spacer, listed are a methylene group and an ethylene group.

2. The photoelectric conversion element of item 1, wherein R₁ in Formula (1) represents t-butyl group, i-propyl group, or triethylmethyl group.
3. The photoelectric conversion element of item 1, wherein X in Formula (1) represents a substituted or non-substituted cyclohexane ring.
4. The photoelectric conversion element of item 1, wherein R₂ in Formula (1) represents a single bond.
5. The photoelectric conversion element of item 1, wherein B in Formula (1) represents a carboxyl group.
6. The photoelectric conversion element of any one of items 1 to 5, wherein the semiconductor represents titan oxide.
7. The photoelectric conversion element of any one of items 1 to 6, wherein the photoelectric conversion layer is formed on the semiconductor by absorbing a dye after absorbing the compound.
8. The photoelectric conversion element of any one of items 1 to 7, wherein the charge transporting layer comprises a p-type compound semiconductor.
9. A solar cell comprising the photoelectric conversion element of any one of items 1 to 8.

It becomes possible in the present invention to provide a photoelectric conversion element, and specifically to a photoelectric conversion element and a solar cell exhibiting high photoelectric conversion efficiency and durability for a light irradiation. Specifically, in the case of the charge transporting layer being highly conductive solid, the effect is remarkable.

### DETAILED DESCRIPTION OF THE INVENTION

### (Photoelectric Conversion Element)

The photoelectric conversion element of the present invention comprises a substrate, provided thereon a first electrode, a photoelectric conversion layer, a charge transporting layer, and a second electrode in this order, and the photoelectric conversion layer contains the above compound and a semiconductor sensitized dye is absorbed thereto. One of the first electrode or the second electrode is transparent and light is irradiated to the transparent electrode side. When the first electrode is transparent, the substrate is also transparent, and light is irradiated to the substrate side. When the second electrode is transparent and light is irradiated to the second electrode side, the substrate may be opaque. In view of easiness for producing transparent electrode or durability, it is preferable that the first electrode and substrate are transparent.

Terminals are placed on the first electrode and the second electrode in the photoelectric conversion element and light is irradiated to the transparent electrode side, whereby photo current can be derived.

### (Photoelectric Conversion Layer)

### (Semiconductor)

Usable examples of the semiconductor employed for a photoelectric conversion layer include an elemental substance such as silicon, germanium or the like, a compound containing an element in Groups 3-5 and Groups 13-15 of the periodic table (referred to also as the element periodic table), a metal chalcogenide such as oxide, sulfide, selenide or the like, a metal nitride, and so forth.

Preferable examples of metal chalcogenide include an oxide of titanium, tin, zinc, iron, tungsten, zirconium, hafnium, strontium, indium, cerium, yttrium, lanthanum, vanadium, niobium or tantalum; a sulfide of cadmium, zinc, lead, silver, antimony or bismuth; a selenide of cadmium or lead; a telluride of cadmium; and so forth. Examples of other compound-semiconductors include a phosphide of zinc, gallium, indium, cadmium or the like; a selenide of gallium-arsenic or copper-indium; a sulfide of copper-indium; a nitride of titanium; and so forth.

Specific examples include TiO₂, SnO₂, Fe₂O₃, WO₃, ZnO, Nb₂O₅, CdS, ZnS, PbS, Bi₂S₃, CdSe, CdTe, GaP, InP, GaAs, CuInS₂, CuInSe₂, Ti₃N₄ and so forth. Of these, TiO₂, ZnO, SnO₂, Fe₂O₃, WO₃, Nb₂O₅, CdS and PbS are preferably usable, TiO₂ and Nb₂O₅ are more preferably usable, and TiO₂ (titanium oxide) is most preferably usable.

As a semiconductor employed for a photoelectric conversion layer, the above-described plural semiconductors may be used in combination. For example, several kinds of the above-described metal oxide or metal sulfide may be used in combination, and 20% by weight of titanium nitride (Ti₃N₄) may be mixed in titanium oxide semiconductor to be used. The zinc oxide/tin oxide composite described in J. Chem. Soc., Chem. Commun., 15 (1999) may also be applied. In this case, when a component other than metal oxide or metal sulfide is added as a semiconductor, a content of such the addition component is preferably 30% by mass or less with respect to the metal oxide or metal sulfide semiconductor.

### <<Preparation of Semiconductor Layer>>

A method of preparing a semiconductor layer constituting the semiconductor will be described.

In cases where a semiconductor is particle-shaped, a semiconductor layer may be prepared by coating or spraying semiconductor particles onto a conductive support. Further, in cases where the semiconductor is in the form of a film, and is not supported on the conductive support, the semiconductor layer is preferably prepared by attaching the semiconductor onto the conductive support.

As a preferable embodiment of a semiconductor layer formed constituted in the present invention, provided is a method of forming via calcination employing semiconductor particles provided on the above-described conductive support.

When a semiconductor of the present invention is prepared via calcination, the semiconductor is preferably subjected to a sensitization (adsorption, filling in a porous layer, and so forth) treatment employing a sensitizing dye after calcination. After the calcination, specifically, the compound is preferably subjected to the sensitization treatment rapidly before adsorbing water to the semiconductor.

Next, a method of forming a semiconductor layer via calcination employing semiconductor particles, which is preferably utilized in the present invention, will be described in detail.

### (Preparation of Semiconductor Powder-Containing Coating Solution)

First, a semiconductor powder-containing coating solution is prepared. The primary particle diameter of this semiconductor powder is preferably as fine as possible. The semiconductor powder preferably has a primary particle diameter of 1-5,000 nm, and more preferably has a primary particle diameter of 2-50 nm. The coating solution containing the semiconductor powder can be prepared by dispersing the semiconductor powder in a solvent. The semiconductor powder dispersed in the solvent is dispersed in the form of the primary particle. The solvent is not specifically limited as long as it can disperse the semiconductor powder.

As the foregoing solvent, water, an organic solvent, and a mixture of water and an organic solvent are included. As the organic solvent, alcohol such as methanol, ethanol or the like, ketone such as methyl ethyl ketone, acetone, acetylacetone, or the like and hydrocarbon such as hexane, cyclohexane or the like are usable. A surfactant and a viscosity controlling agent (polyhydric alcohol such as polyethylene glycol or the like) can be added into a coating solution, if desired. The content of the semiconductor powder in the solvent is preferably 0.1-70% by mass, and more preferably 0.1-30% by mass.

### (Coating of Semiconductor Powder-Containing Coating Solution and Calcination Treatment of Formed Semiconductor Layer)

The semiconductor powder-containing coating solution obtained as described above is coated or sprayed onto the conductive support, followed by drying, and then burned in air or inactive gas to form a semiconductor layer (referred to also as a semiconductor film) on the conductive support.

The layer formed via coating the semiconductor powder-containing coating solution onto the conductive support, followed by drying is composed of an aggregate of semiconductor particles, and the particle diameter corresponds to the primary particle diameter of the utilized semiconductor powder.

The semiconductor particle layer formed on a conductive layer of the conductive support or the like in such the way is subjected to a calcination treatment in order to increase mechanical strength and to produce a semiconductor layer firmly attached to a substrate, since the semiconductor particle layer exhibits bonding force with the conductive support, as well as bonding force between particles, and also exhibits weak mechanical strength.

In the present invention, this semiconductor layer may have any structure, but a porous structure layer (referred to also as a porous layer possessing pores) is preferable.

The semiconductor layer preferably has a porosity of 10% by volume or less, more preferably has a porosity of 8% by volume or less, and most preferably has a porosity of 0.01-5% by volume. In addition, the porosity of the semiconductor layer means through-hole porosity in the direction of thickness of a dielectric, and it can be measured by a commercially available device such as a mercury porosimeter (Shimadzu Pore Analyzer 9220 type) or the like.

A semiconductor layer as a calcine film having a porous structure preferably has a thickness of at least 10 μm, and more preferably has a thickness of 500-30,000 nm.

A calcination temperature of 1,000° C. or less is preferable, a calcination temperature of 200-800° C. is more preferable, and a calcination temperature of 300-800° C. is still more preferable in view acquisition of a calcine film having the above-described porosity by suitably preparing real surface area of the calcine film during calcination treatment.

Further, a ratio of the real surface area to the apparent surface area can be controlled by a diameter and specific surface area of the semiconductor particle, the calcination temperature and so forth. After conducting a heat treatment, chemical plating employing an aqueous solution of titanium tetrachloride or electrochemical plating employing an aqueous solution of titanium trichloride may be conducted in order to increase the surface area of a semiconductor particle and purity in the vicinity of the semiconductor particle, and to increase an electron injection efficiency from a dye to a semiconductor particle.

### (Sensitizing Dye)

According to the present invention, a sensitizing dye is supported to the semiconductor. In view of charge injection efficiency to a semiconductor, the sensitizing dye preferably has a carboxyl group. Specific examples of sensitizing dyes are listed below, however the present invention is not limited thereto.

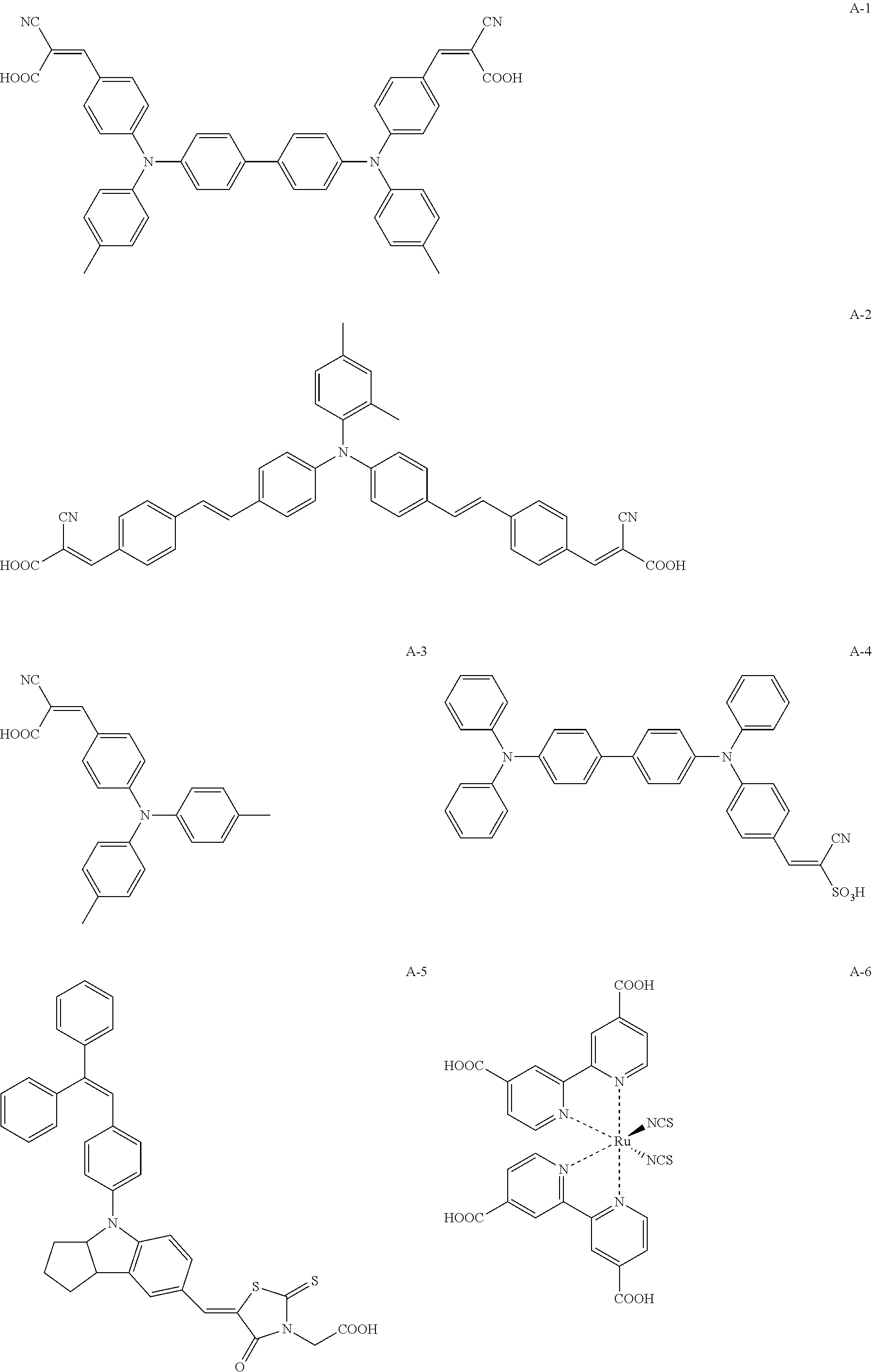

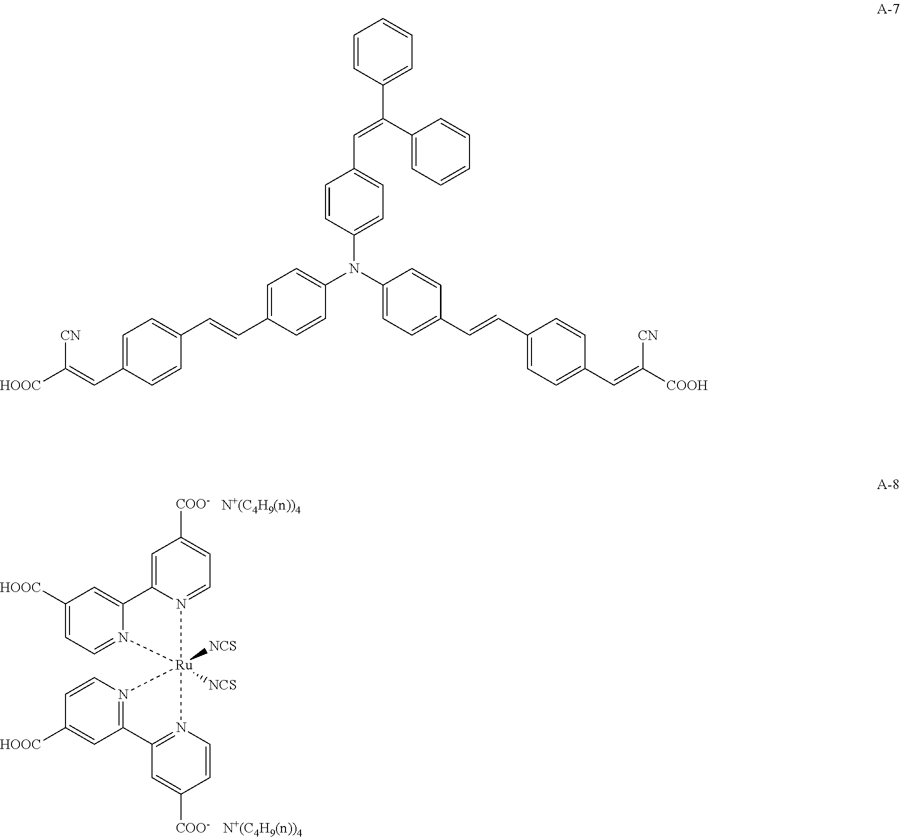

### (Sensitization Treatment of Semiconductor)

According to the present invention, it is preferable to absorb the absorption compound to the semiconductor before the sensitizing dye is supported to the semiconductor. The laminated body 1 is prepared by immersing a laminated body with the foregoing semiconductor layer (laminated body comprising a substrate provided thereon the first electrode and semiconductor layer in this order) into a solution prepared by dissolving the absorption compound in a suitable solvent and by absorbing the absorption compound onto the semiconductor.

In this case, the semiconductor layer is preferably formed via calcination and bubbles in the layer are preferably removed by conducting a reduced pressure treatment, so as that the absorption compound can easily be penetrated deeply into the inside of the semiconductor layer. Such treatment is specifically preferable when the semiconductor layer (semiconductor film) possesses a porous structure film.

Sensitization treatment of semiconductor is preferably carried out by dissolving the sensitizing dye in a suitable solvent and by immersing the laminated body 1 into the solution.

The solvent to dissolve the foregoing sensitizing dye in the present invention is not specifically limited as long as the solvent can dissolve the foregoing compound, and neither dissolve the semiconductor nor react with the semiconductor. However, the solvent is preferably subjected to deaeration and purification via distillation to prevent penetration of moisture and gas dissolved in the solvent into the semiconductor layer so as to avoid the sensitization treatment such as adsorption of the foregoing compound or the like.

Examples of preferably usable solvents to dissolve the foregoing compound include an alcohol based solvent such as methanol, ethanol, n-propanol, t-butylalcohol and so forth; a ketone type solvent such as acetone, methylethyl ketone and so forth; an ether based solvent such as diethyl ether, diisopropyl ether, tetrahydrofuran, 1,4-dioxane and so forth; nitrile type solvent such as acetonitrile, propionitrile and so forth and a halogenated hydrocarbon solvent such as methylene chloride, 1,1,2-trichloroethane and so forth. Solvent mixture may be used. Specifically preferred are methanol, ethanol, t-butylalcohol, and acetonitrile.

As to time to immerse a substrate on which the semiconductor layer (semiconductor film) is formed via calcination in a solution containing a sensitizing dye, it is preferably 1-48 hours, and more preferably 3-24 hours at 25° C. in order to sufficiently make progress of adsorption by penetrating deeply into the semiconductor layer and to prevent decomposed products prepared via decomposition of the sensitizing dye from hindering the absorption of the sensitizing dye in the solvent. This effect is remarkable when the semiconductor film is specifically a porous structure film. However, the immersion time is that at 25° C. and is not always applied when the temperature is varied.

During the immersion, a solution containing a sensitizing dye employed in the present invention may be heated up to the temperature of no boiling, as long as the foregoing sensitizing dye is not decomposed. The temperature range is preferably 10-100° C., and more preferably 25-80° C., as long as the solution is not boiled in the foregoing temperature range.

When a sensitization treatment is conducted employing a sensitizing dye of the present invention, the sensitizing dye may be used singly or plural kinds of sensitizing dyes may be used in combination. The total carrying amount of a sensitizing dye of the present invention per m² of a semiconductor layer is preferably 0.01-100 mmol, more preferably 0.1-50 mmol, and still more preferably 0.5-20 mmol.

Further, the sensitizing dye having carboxyl group preferable in the present invention may be used in combination with other sensitizing dyes. With respect to the sensitizing dye used in combination, any sensitizing dye can be employable as long as it can sensitize the semiconductor by spectral sensitization. At least two sensitizing dyes are preferably employed in combination, so that the wavelength region for photoelectric conversion is expanded as broad as possible to achieve photoelectric conversion efficiency. Further, species and ratio of sensitizing dyes used in combination may be selected so as to match the wavelength region and for intensity distribution of the light source.

In the case of the photoelectric conversion element of the present invention used for a solar cell described later, at least two sensitizing dyes differing in absorption wavelength ranges are preferably used, so that the wavelength region for photoelectric conversion is expanded as broad as possible to achieve effective utilization of solar light.

Of the sensitizing dyes used in combination, in total view of reactivity for photoelectron reaction, light durability, and photochemical stability, metal complex dye, phthalocyanine based dye, porphyrin based dye, and polymethine based dye are preferably used.

Examples of the commonly known other sensitizing dyes usable in combination with the sensitizing dye having carboxyl group in the present invention include sensitizing dyes disclosed in U.S. Pat. No. 4,684,537, U.S. Pat. No. 4,927,721, U.S. Pat. No. 5,084,365, U.S. Pat. No. 5,350,644, U.S. Pat. No. 5,463,057, U.S. Pat. No. 5,525,440, JP-A No. 7-249790, and JP-A No. 2000-150007.

In order to carry a sensitizing dye of the present invention with a semiconductor layer, in general, is dissolved in an appropriate solvent (ethanol or the like) and a well-dried semiconductor is immersed into the solution for a long duration.

When using plural kinds of sensitizing dyes of the present invention or using the sensitizing dye in combination with other sensitizing dyes having carboxyl group in the present invention, a mixed solution of the dyes may be prepared or solutions of the individual dyes are prepared, in which a semiconductor is immersed. In the latter, immersion in the individual solutions may be conducted in any order. Further, semiconductor particles which were previously adsorbed with the sensitizing dyes may be mixed.

In the case of a semiconductor layer having high porosity, it is preferred to subject the semiconductor to an adsorption treatment of the sensitizing dye (sensitizing treatment of semiconductor) before moisture or water vapor is adsorbed onto the semiconductor surface or into pores in the interior of the semiconductor.

### (Compound of the Present Invention)

Compound described above is represented by Formula (1).

R₁—X—R₂—B, Formula (1)

wherein R₁ represents C(R₃)(R₄)(R₅), R₃, R₄, and R₅ represents a hydrogen atom, a methyl group or an ethyl group, provided that R₃, R₄, and R₅ are not simultaneously a hydrogen atom, X represents a substituted or non-substituted cyclohexane ring, a substituted or non-substituted benzene ring, or a substituted or non-substituted pyrimidine ring, R₂ represents a methylene group, an ethylene group, or a single bond, B represents a carboxyl group, a sulfo group or a phosphono group. Substituent of X may include alkyl group or alkoxy group each of which may have branched-chain having 1-6 carbons, halogen or cyano group. The substituent may be the same as R₁. Of these, in view of durability, X is preferable a substituted or non-substituted cyclohexane ring, R₂ is preferable a single bond, and B is preferable a carboxyl group.

R₁ is preferable t-butyl group, i-propyl group, or triethylmethyl group. Of these, t-butyl group is specifically preferable due to maintain stable characteristics by effective prevention from approaching charge transporting material and by stable absorption. Further, R₁ is preferable to substitute at para position in view of maintaining prevention for reverse electron transfer without bad effect on absorption group.

The compound represented by Formula (1) may be dissolved in the same solution used for absorption of dye, or absorbed in the same manner as dye after absorbing dye. Of these, preferred is absorbing above compound before absorbing dye. It is considered that to absorb above compound represented by Formula (1) before absorbing dye can inhibit association of dyes and prevent reverse electron transfer between dyes.

Specific examples of the compounds include following compounds.

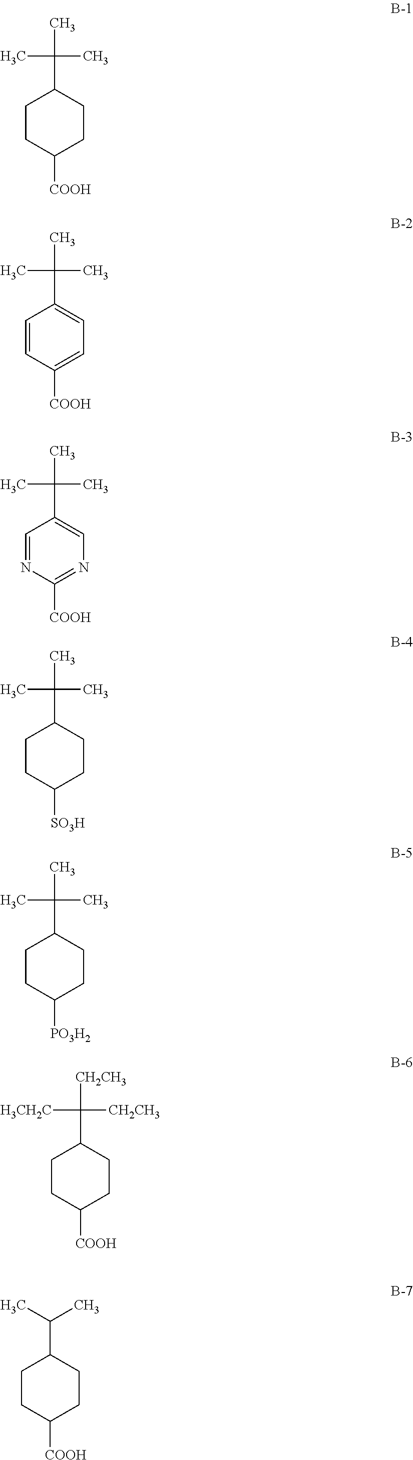

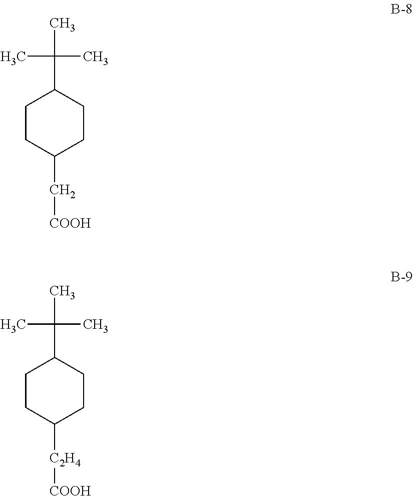

Above described compounds can be commercially available from a reagent manufacture or can be synthesized by the conventional method.

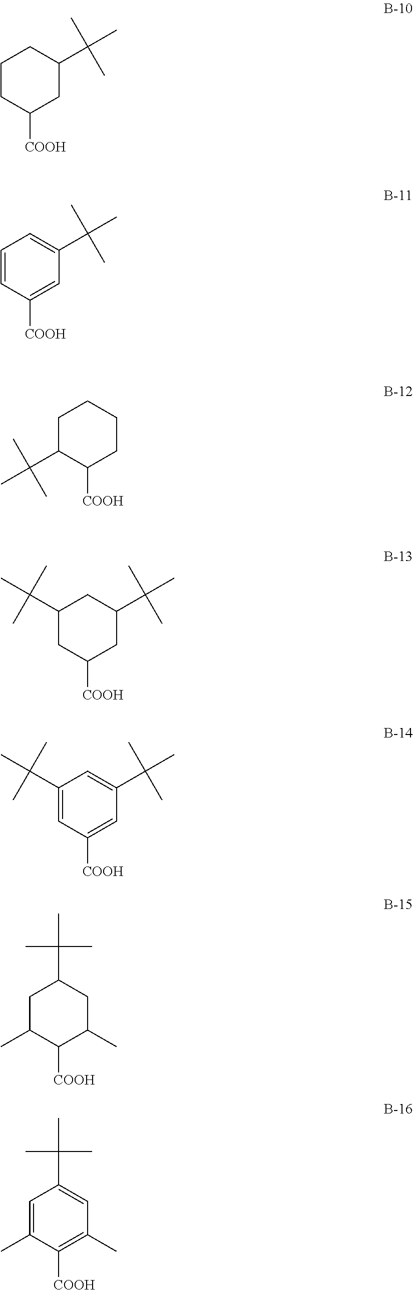

The solvent to dissolve the foregoing sensitizing dye in the present invention is not specifically limited as long as the solvent can dissolve the foregoing compound, and neither dissolve the semiconductor nor react with the semiconductor. However, the solvent is preferably subjected to deaeration and purification via distillation to prevent penetration of moisture and gas dissolved in the solvent into the semiconductor layer so as to avoid the sensitization treatment such as adsorption of the foregoing compound or the like.

Examples of preferably usable solvents to dissolve the foregoing compound include an alcohol based solvent such as methanol, ethanol, n-propanol, t-butylalcohol and so forth; a ketone type solvent such as acetone, methylethyl ketone and so forth; an ether based solvent such as diethyl ether, diisopropyl ether, tetrahydrofuran, 1,4-dioxane and so forth; nitrile type solvent such as acetonitrile, propionitrile and so forth and a halogenated hydrocarbon solvent such as methylene chloride, 1,1,2-trichloroethane and so forth. Solvent mixture may be used. Specifically preferred are methanol, ethanol, t-butylalcohol, and acetonitrile.

As to time to immerse a substrate on which the semiconductor layer is formed via calcination in a solution containing the compound, it is preferably 1-48 hours, and more preferably 3-24 hours at 25° C. in order to sufficiently make progress of adsorption by penetrating deeply into the semiconductor layer and to prevent decomposed products prepared via decomposition of a compound from hindering the absorption of the sensitizing dye. This effect is remarkable when the semiconductor film is specifically a porous structure film. However, the immersion time is that at 25° C. and is not always applied when the temperature is varied.

During the immersion, a solution containing a compound employed in the present invention may be heated up to the temperature of no boiling, as long as the foregoing compound is not decomposed. The temperature range is preferably 10-100° C., and more preferably 25-80° C., as long as the solution is not boiled in the foregoing temperature range.

The total carrying amount of a compound of the present invention per m² of a semiconductor layer is preferably 0.01-100 mmol, more preferably 0.1-50 mmol, and still more preferably 0.5-20 mmol.

### (Substrate)

As a substrate, transparent substrate is preferable utilized which is formed by transparent material like a glass plate and a plastic film.

### (First Electrode, Second Electrode)

At least one of the first electrode or the second electrode is a transparent conductive layer, but it is preferable that the first electrode is a transparent electrode. An electrode facing to the transparent electrode may be an opaque conductive layer.

The term “transparent conductive layer” means that the conductive layer described above is “substantially transparent”. The term “substantially transparent” means that transmittance is at least 10%, preferably at least 50%, and more preferably at least 80%. Examples of the material used for the transparent conductive layer include ITO, FTO and ZnO. Of these, FTO is preferable in view of high productivity and high transparency.

Examples of the material used for the opaque conductive layer include a metal such as platinum, gold, silver, copper, aluminum, rhodium and indium or conductive metal oxide such as indium oxide, tin oxide, zinc oxide, or gallium oxide and composite oxide thereof or carbon. In the case of using tin oxide, fluorine-doped tin oxide is preferable. The opaque conductive layer preferably has a surface resistance of 50 Ω/cm² or less and more preferably has a surface resistance of 10 Ω/cm² or less.

The opaque conductive layer preferably is a material having catalytic power which accelerates oxidation reaction of I₃⁻ ion or reduction reaction of other redox ion. Specific examples of these materials include platinum electrode, platinum being plated or vapor deposited on the surface of conductive material, rhodium metal, ruthenium metal, carbon or polypyrrole.

### (Charge Transporting Layer)

Charge transporting layer used for the present invention will be described.

Charge transporting layer is a layer which functions to reduce oxidized dye rapidly and to transport hole injected at boundary of dye to opposite electrode.

Charge transporting layer of the present invention is constituted mainly by a dispersion of redox electrolyte or p-type compound semiconductor (charge transporting material) as hole transporting material. A p-type compound semiconductor is preferably utilized as main component in view of charge transporting layer being solid.

As the redox electrolyte, I⁻/I₃⁻ system, Br⁻/Br₃⁻ system and quinone/hydroquinone system are cited. Such the redox electrolyte can be obtained by a commonly known method, and the electrolyte of I⁻/I₃⁻ system, for example, can be obtained by mixing an ammonium salt of iodine and iodine. When such the dispersion is a solution, the dispersion is called a liquid electrolyte; when one being a solid at room temperature is dispersed in a polymer, it is called a solid polymer electrolyte; and when it is dispersed in a material in the form of a gel, it is called a gel electrolyte. When the liquid electrolyte is employed as a liquid electrolyte, an electrochemically inactive substance is used as the solvent such as acetonitrile, propylene carbonate, ethylene carbonate and so forth. Examples of the solid polymer electrolyte are disclosed in JP-A No. 2001-160427, and examples of the gel electrolyte are disclosed in “Hyomen Kagaku (Surface Science)” Vol. 21, No. 5, pages 288-293.

A p-type compound semiconductor has preferably a large band gap in order not to disturb dye absorption. The band gap of the p-type compound semiconductor employed in the present invention is preferably 2 eV or more, and more preferably 2.5 eV or more. The ionization potential of a p-type compound semiconductor needs to be smaller than the ionization potential of a dye adsorption electrode in order to reduce a dye hole. Although the preferable range of the ionizing potential of a p-type compound semiconductor employed for a charge transport layer may differ depending on the employed dye, generally, the ionizing potential is preferably 4.5 eV or more and 5.5 eV or less, and preferably 4.7 eV or more and 5.3 eV or less.

As a p-type compound semiconductor, an aromatic amine derivative excellent in transporting ability for a positive hole is desirable. For this reason, when a charge transport layer is constituted mainly by an aromatic amine derivative, photoelectric conversion efficiency can be improved more. As the aromatic amine derivative, it is particularly desirable to use a triphenyl diamine derivative. The triphenyl diamine derivative is excellent particularly in transporting capacity for a positive hole among the aromatic amine derivative. Further, any one of a monomer, an oligomer, a prepolymer, and a polymer of such an aromatic amine derivative may be employable, and a mixture of them may be employable. Since a monomer, an oligomer, and a prepolymer have relatively low molecular weight, they have high solubility to a solvent such as an organic solvent. Accordingly, in the case that a charge transport layer is formed by a coating method, there is an advantage that a charge transport layer material can be prepared more easily. Among them, as an oligomer, it is desirable to use a dimer or a trimer.

Specific examples of an aromatic tertiary amine compound include N,N,N′,N′-tetraphenyl-4,4″-diaminophenyl; N,N′-diphenyl-N,N′-bis(3-methylphenyl)-[1,1′-biphenyl]-4,4′-diamine (TPD); 2,2-bis(4-di-p-tolyl aminophenyl)propane; 1,1-bis(4-di-p-trylaminophenyl)cyclohexane, N,N,N′,N′-tetra-p-tryl-4,4′-diaminobiphenyl, 1,1-bis(4-di-p-trylaminophenyl)-4-phenyl cyclohexane, bis(4-dimethylamino-2-methylphenyl)phenylmethane, bis(4-di-p-trylaminophenyl)phenylmethane, N,N′-diphenyl-N,N′-di(4-methoxyohenyl)-4,4′-diaminobiphenyl, N,N,N′,N′ tetraphenyl-4,4′-diaminodiphenyl ether, 4,4′-bis(diphenylamino) quadriphenyl; N,N,N-trip-tolyl)amine; 4-(di-p-tolylamino)-4′-[4-(di-p-tolyl amino)styryl]stilbene; 4-N,N-diphenylamino-(2-diphenylvinyl)benzene; 3-methoxy-4′-N,N-diphenylamino stilbenzene; N-phenylcarbazole; further a compound having two condensed aromatic rings in a molecule, such as 4,4′-bis[(N-(1-naphthyl)-N-phenylamino)]biphenyl (NPD) which is disclosed in U.S. Pat. No. 5,061,569; a compound in which three triphenylamine units are bonded in starburst type, such as 4,4′,4″-tris[N-(3-methylphenyl)-N-phenylamino]triphenylamine (MTDATA) which is disclosed in JP-A No. 4-308688; and the like.

Furthermore, employable is a polymeric material in which these materials are introduced in a polymer chain or these materials are made as a main chain of a polymer.

As p-type compound semiconductors other than the aromatic amine derivative, a thiophene derivative, a pyrrole derivative, a stilbene derivative, etc. are employable.

Although specific examples of a p-type compound semiconductor are shown below, the present invention is not limited to these examples.

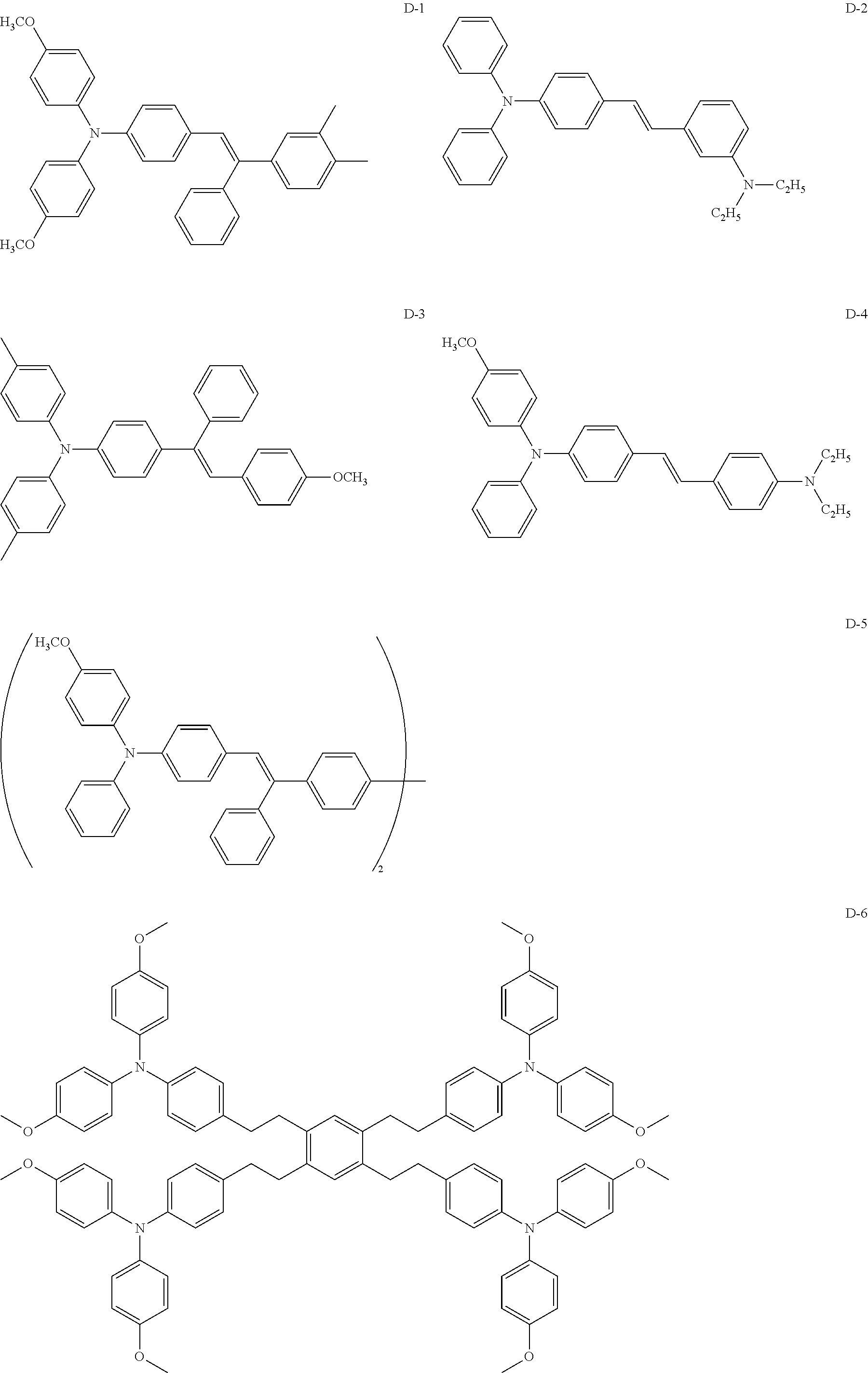

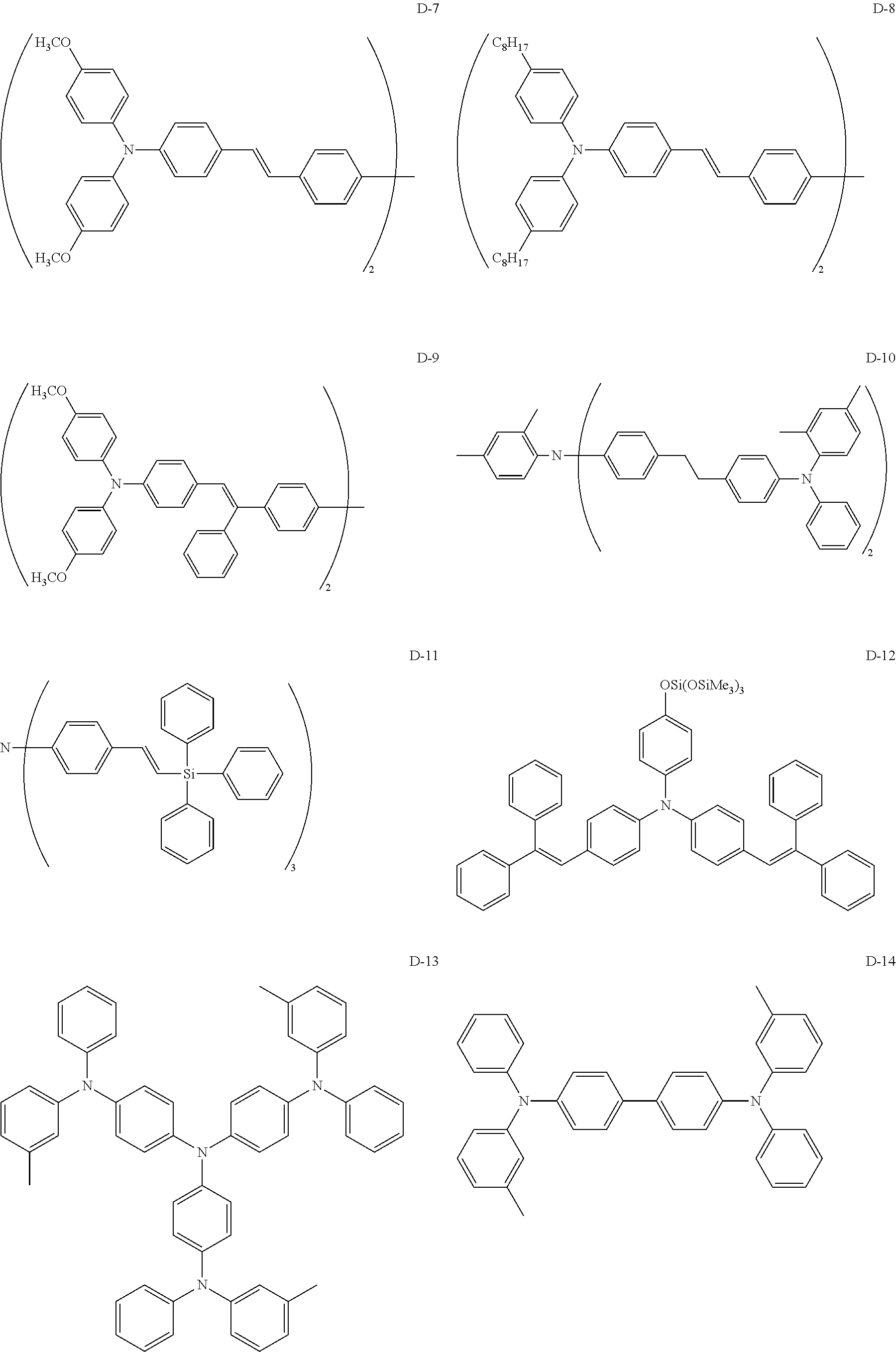

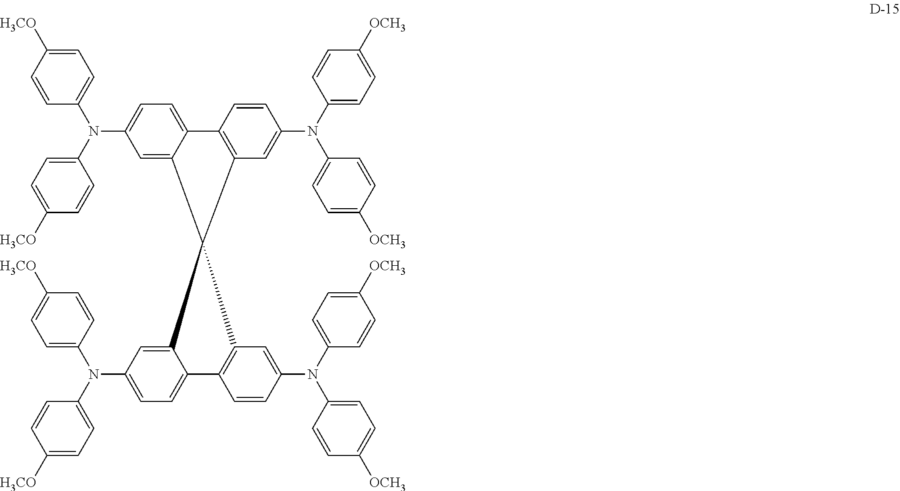

### EXAMPLES

Examples of the present invention will now specifically be described.

### Example 1

### Preparation of Photoelectric Conversion Element SC-1

A solar cell (photoelectric conversion element) is prepared as follows.

### (Forming of Barrier Layer)

A conductive glass substrate of fluorine doped tin oxide (FTO) having sheet resistance 20Ω/□ was used for the first electrode. A diluted solution was prepared by adding tetrakisisopropoxy titanium 1.2 ml and acetyl acetone 0.8 ml into ethanol 18 ml. Resulting solution was dropped and spin-coated on the substrate and then heated for 8 minutes at 450° C., whereby formed was a barrier layer of thin titanium oxide film having thickness of 30-50 nm on the transparent conductive layer (FTO).

### (Preparation of Photoelectric Conversion Layer)

Titanium oxide paste was prepared by dispersing anatase type titanium oxide having primary average diameter of 18 nm (averaged observed by micrometer) and ethyl cellulose into 10% acetyl acetone-water. Resulting paste was coated on the FTO glass substrate on which above barrier layer was formed by screen printing method (coating area: 25 mm² (5 mm×5 mm)). Then, calcining for 15 minutes at 500° C., whereby a thin titanium oxide film having thickness of 2.5 μm was obtained.

Then, compound B-1 was dissolved into mixed solvent of acetonitrile:t-butyl alcohol=1:1 to prepare 5×10⁻⁴ mol/l solution. FTO glass substrate coated and sintered above titanium oxide was immersed into this solution for 3 hours at room temperature, whereby compound B-1 was absorption treated.

Then, exemplifying compound A-7 for sensitizing dye was dissolved into mixed solvent of acetonitrile: t-butyl alcohol=1:1 to prepare 5×10⁻⁴ mol/l solution. FTO glass substrate having titanium oxide absorbed by above compound B-1 was immersed into this solution for 3 hours at room temperature, whereby dye was absorption treated to form photoelectric conversion layer and semiconductor electrode 1 was obtained.

### (Preparation of Charge Transporting Layer)

On the photoelectric conversion layer of semiconductor electrode 1, chlorobenzene solution of exemplifying compound D-15 for charge transporting material (170 mM), Li[(CF₃SO₂)₂N] (15 mM) and t-butylpyrridine (50 mM) was coated via spin coating method, whereby charge transporting layer having dry thickness of 10 μm was formed. Herein, spin coating was carried out at 500 rpm.

Then, semiconductor layer/charge transporting layer was air-dried. Further, by vapor deposition method, the second electrode was prepared and photoelectric conversion element SC-1 was obtained.

### Example 2

### (Preparation of Photoelectric Conversion Element SC-2)

Acetonitrile solution (electropolymerization solution) of dimmer of thiophene based monomer EDOT (ethylene dioxy thiophene) (K192: produce by Kairon Kern) in concentration of 1×10⁻³ mol/l and Li[(CF₃SO₂)₂N] in concentration of 0.1 mol/l was prepared. Semiconductor electrode 2 on which the photoelectric conversion layer was prepared in the same manner as Example 1 was immersed into above solution. Semiconductor electrode 2 was used for functional electrode, platinum wire was used for opposite electrode, Ag/Ag⁺ (AgNO₃ 0.01 M) was used for reference electrode and hold voltage was set at −0.16 V. Dimer of EDOT was polymerized by holding voltage to the extent of integrated charge quantity 4 mC, while light was irradiated from the direction of semiconductor side by using xenon lump, light intensity at the surface of semiconductor being 22 mW/cm² and wavelength of 430 nm or less being cut, whereby charge transporting layer having PEDOT as charge transporting material was formed on the surface of the semiconductor electrode 2. Obtained laminated body of semiconductor electrode/charge transporting layer was washed by acetonitrile and dried.

Herein, obtained charge transporting layer was insoluble polymer film to solvent.

Subsequently, obtained laminated body was immersed into acetonitrile solution containing Li[(CF₃SO₂)₂N] 15×10⁻³ mol/l and tert-butyl pyridine 50×10⁻³ mol/l for 10 minutes.

Subsequently, laminated body of semiconductor electrode/charge transporting layer was air-dried, followed by vapor depositing gold in 60 nm thickness, whereby the second electrode was prepared and photoelectric conversion element SC-2 was obtained.

### (Preparation of Photoelectric Conversion Elements SC-3, 5, 7, 9, 11, 13, 15, 17, 19, 21, 23, 25, 27, 29, 31, 33, 35, 37, 39, 41, 43, 45, 47)

Photoelectric conversion elements SC-3, 5, 7, 9, 11, 13, 15, 17, 19, 21, 23, 25, 27, 29, 31, 33, 35, 37, 39, 41, 43, 45, 47 were prepared in the same manner as the preparation of photoelectric conversion element SC-1, except for changing sensitizing dye and compound to a compound listed in Tables 1 and 2.

Herein, in the preparation of SC-45 and 47, charge transporting layer was formed without adding t-butyl pyridine (C-2) in the chlorobenzene solution.

Compounds C-1 and C-2 in Table 2 were shown below.

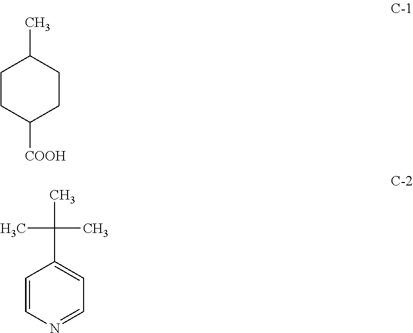

### (Preparation of Photoelectric Conversion Elements SC-4, 6, 8, 10, 12, 14, 16, 18, 20, 22, 24, 26, 28, 30, 32, 34, 36, 38, 40, 42, 44, 46, 48)

Photoelectric conversion elements SC-4, 6, 8, 10, 12, 14, 16, 18, 20, 22, 24, 26, 28, 30, 32, 34, 36, 38, 40, 42, 44, 46, 48 were prepared in the same manner as the preparation of photoelectric conversion element SC-1, except for changing sensitizing dye and compound to a compound listed in Tables 1 and 2.

### (Evaluation of Photoelectric Conversion Element)

Following evaluations were carried out for each photoelectric conversion element.

### (Evaluation of Photoelectric Conversion Efficiency)

Photoelectric conversion efficiency were measured by using solar simulator (product of Eko Instruments Co., Ltd) via exposure of artificial sunlight from a xenon lamp at an incident light intensity of 100 mW/cm² through AM filter (AM-1.5) under the condition of covering a semiconductor layer with a mask of 5×5 mm². That is, the current-voltage characteristics are measured by a I-V tester to obtain short circuit current density Jsc (mA/cm²), open circuit voltage Voc (V), and form factor (F. F.), whereby photoelectric conversion efficiency η (%) was determined.

Photoelectric conversion efficiency η (%) was determined based on the following Equation (A).

η=100×(Voc×Jsc×F.F.)/P, Equation (A)

wherein P represents the forgoing incident light intensity (mW/cm²), Voc represents open circuit voltage (V), Jsc represents short circuit current density (mA/cm²), and F.F represents form factor.

### (Evaluation of Durability)

After measuring the photoelectric conversion efficiency described above, the photoelectric conversion element was further short-circuited. After exposing artificial sunlight at an incident light intensity of 120 mW/cm² for 720 hours, the current-voltage characteristics are measured to obtain short circuit current density Jsc₁, open circuit voltage Voc₁, and photoelectric conversion efficiency η₁, whereby durability rate was determined by the following equation.

Durability rate=η₁/η.

These results are shown in Tables 1 and 2.

TABLE 1

| Photoelectric | | | | Charge | Initial | | | | Characteristics after light | | | | Durability | |
|---|---|---|---|---|---|---|---|---|---|---|---|---|---|---|
| conversion | Com- | Sensitizing | Order of | transporting | characteristics | | | | exposure | | | | ratio | |
| element No. | pound | dye | absorption | material | Voc | Jsc | FF | η | Voc₁ | Jsc₁ | FF₁ | η₁ | (η₁/η) | Remarks |
| SC-1 | B-1 | A-7 | B→A | D-15 | 790 | 8.1 | 0.41 | 2.6 | 760 | 8.0 | 0.38 | 2.3 | 0.88 | Inv. |
| SC-2 | B-1 | A-7 | B→A | PEDOT | 910 | 4.7 | 0.70 | 3.0 | 870 | 4.7 | 0.60 | 2.5 | 0.82 | Inv. |
| SC-3 | B-1 | A-8 | B→A | D-15 | 800 | 7.9 | 0.42 | 2.7 | 760 | 7.8 | 0.39 | 2.3 | 0.87 | Inv. |
| SC-4 | B-1 | A-8 | B→A | PEDOT | 910 | 4.5 | 0.68 | 2.8 | 860 | 4.5 | 0.59 | 2.3 | 0.82 | Inv. |
| SC-5 | B-2 | A-7 | B→A | D-15 | 770 | 6.7 | 0.39 | 2.0 | 760 | 6.6 | 0.37 | 1.9 | 0.92 | Inv. |
| SC-6 | B-2 | A-7 | B→A | PEDOT | 890 | 3.4 | 0.71 | 2.1 | 890 | 3.3 | 0.65 | 1.9 | 0.89 | Inv. |
| SC-7 | B-2 | A-8 | B→A | D-15 | 770 | 6.5 | 0.42 | 2.1 | 760 | 6.4 | 0.40 | 1.9 | 0.93 | Inv. |
| SC-8 | B-2 | A-8 | B→A | PEDOT | 880 | 3.2 | 0.67 | 1.9 | 870 | 3.1 | 0.63 | 1.7 | 0.90 | Inv. |
| SC-9 | B-3 | A-7 | B→A | D-15 | 800 | 7.4 | 0.41 | 2.4 | 770 | 7.2 | 0.39 | 2.2 | 0.89 | Inv. |
| SC-10 | B-3 | A-7 | B→A | PEDOT | 900 | 4.1 | 0.71 | 2.6 | 890 | 4.1 | 0.62 | 2.3 | 0.86 | Inv. |
| SC-11 | B-3 | A-8 | B→A | D-15 | 810 | 7.2 | 0.42 | 2.4 | 760 | 7.1 | 0.40 | 2.2 | 0.88 | Inv. |
| SC-12 | B-3 | A-8 | B→A | PEDOT | 910 | 3.9 | 0.70 | 2.5 | 880 | 3.9 | 0.62 | 2.1 | 0.86 | Inv. |
| SC-13 | B-4 | A-7 | B→A | D-15 | 680 | 8.0 | 0.37 | 2.0 | 570 | 7.5 | 0.30 | 1.3 | 0.64 | Inv. |
| SC-14 | B-4 | A-7 | B→A | PEDOT | 790 | 4.6 | 0.66 | 2.4 | 680 | 4.2 | 0.58 | 1.7 | 0.69 | Inv. |
| SC-15 | B-4 | A-8 | B→A | D-15 | 690 | 7.8 | 0.40 | 2.2 | 590 | 7.3 | 0.32 | 1.4 | 0.64 | Inv. |
| SC-16 | B-4 | A-8 | B→A | PEDOT | 780 | 4.5 | 0.64 | 2.2 | 660 | 4.1 | 0.56 | 1.5 | 0.67 | Inv. |
| SC-17 | B-5 | A-7 | B→A | D-15 | 700 | 8.0 | 0.36 | 2.0 | 580 | 7.4 | 0.31 | 1.3 | 0.66 | Inv. |
| SC-18 | B-5 | A-7 | B→A | PEDOT | 820 | 4.7 | 0.65 | 2.5 | 700 | 4.1 | 0.58 | 1.7 | 0.66 | Inv. |
| SC-19 | B-5 | A-8 | B→A | D-15 | 690 | 7.9 | 0.40 | 2.2 | 560 | 7.2 | 0.33 | 1.3 | 0.61 | Inv. |
| SC-20 | B-5 | A-8 | B→A | PEDOT | 800 | 4.5 | 0.63 | 2.3 | 680 | 3.9 | 0.57 | 1.5 | 0.67 | Inv. |
| SC-21 | B-6 | A-7 | B→A | D-15 | 800 | 7.6 | 0.41 | 2.5 | 760 | 7.5 | 0.39 | 2.2 | 0.89 | Inv. |
| SC-22 | B-6 | A-7 | B→A | PEDOT | 900 | 4.2 | 0.70 | 2.6 | 860 | 4.2 | 0.61 | 2.2 | 0.83 | Inv. |
| SC-23 | B-6 | A-8 | B→A | D-15 | 790 | 7.3 | 0.42 | 2.4 | 740 | 7.1 | 0.40 | 2.1 | 0.87 | Inv. |
| SC-24 | B-6 | A-8 | B→A | PEDOT | 910 | 4.0 | 0.68 | 2.5 | 850 | 4.0 | 0.60 | 2.0 | 0.82 | Inv. |
| SC-25 | B-7 | A-7 | B→A | D-15 | 770 | 8.2 | 0.41 | 2.6 | 700 | 8.0 | 0.34 | 1.9 | 0.74 | Inv. |
| SC-26 | B-7 | A-7 | B→A | PEDOT | 890 | 4.8 | 0.68 | 2.9 | 810 | 4.6 | 0.56 | 2.1 | 0.72 | Inv. |

TABLE 2

| Photoelectric | | | | Charge | Initial | | | | Characteristics after light | | | | Durability | |
|---|---|---|---|---|---|---|---|---|---|---|---|---|---|---|
| conversion | Com- | Sensitizing | Order of | transporting | characteristics | | | | exposure | | | | ratio | |
| element No. | pound | dye | absorption | material | Voc | Jsc | FF | η | Voc₁ | Jsc₁ | FF₁ | η₁ | (η₁/η) | Remarks |
| SC-27 | B-7 | A-8 | B→A | D-15 | 770 | 8.1 | 0.41 | 2.6 | 700 | 7.8 | 0.35 | 1.9 | 0.75 | Inv. |
| SC-28 | B-7 | A-8 | B→A | PEDOT | 890 | 4.7 | 0.68 | 2.8 | 820 | 4.5 | 0.55 | 2.0 | 0.71 | Inv. |
| SC-29 | B-8 | A-7 | B→A | D-15 | 780 | 8.1 | 0.40 | 2.5 | 740 | 8.0 | 0.36 | 2.1 | 0.84 | Inv. |
| SC-30 | B-8 | A-7 | B→A | PEDOT | 900 | 4.7 | 0.69 | 2.9 | 850 | 4.7 | 0.61 | 2.4 | 0.83 | Inv. |
| SC-31 | B-8 | A-8 | B→A | D-15 | 780 | 7.9 | 0.40 | 2.5 | 730 | 7.8 | 0.38 | 2.2 | 0.88 | Inv. |
| SC-32 | B-8 | A-8 | B→A | PEDOT | 880 | 4.5 | 0.66 | 2.6 | 830 | 4.5 | 0.57 | 2.1 | 0.81 | Inv. |
| SC-33 | B-9 | A-7 | B→A | D-15 | 790 | 8.0 | 0.41 | 2.6 | 720 | 7.8 | 0.33 | 1.9 | 0.72 | Inv. |
| SC-34 | B-9 | A-7 | B→A | PEDOT | 890 | 4.6 | 0.68 | 2.8 | 810 | 4.4 | 0.57 | 2.0 | 0.73 | Inv. |
| SC-35 | B-9 | A-8 | B→A | D-15 | 790 | 8.0 | 0.39 | 2.5 | 700 | 7.6 | 0.32 | 1.7 | 0.69 | Inv. |
| SC-36 | B-9 | A-8 | B→A | PEDOT | 870 | 4.6 | 0.63 | 2.5 | 800 | 4.5 | 0.52 | 1.9 | 0.74 | Inv. |
| SC-37 | B-1 | A-7 | A→B | D-15 | 750 | 7.0 | 0.39 | 2.0 | 680 | 6.2 | 0.34 | 1.4 | 0.70 | Inv. |
| SC-38 | B-1 | A-7 | A→B | PEDOT | 810 | 4.0 | 0.64 | 2.1 | 720 | 3.5 | 0.51 | 1.3 | 0.62 | Inv. |
| SC-39 | B-1 | A-8 | A→B | D-15 | 730 | 6.9 | 0.42 | 2.1 | 670 | 6.1 | 0.33 | 1.3 | 0.64 | Inv. |
| SC-40 | B-1 | A-8 | A→B | PEDOT | 830 | 4.1 | 0.63 | 2.1 | 740 | 3.5 | 0.53 | 1.4 | 0.64 | Inv. |
| SC-41 | None | A-7 | B→A | D-15 | 600 | 8.3 | 0.42 | 2.1 | 390 | 4.2 | 0.33 | 0.5 | 0.26 | Comp. |
| SC-42 | None | A-7 | B→A | PEDOT | 710 | 4.8 | 0.60 | 2.0 | 370 | 3.7 | 0.40 | 0.5 | 0.27 | Comp. |
| SC-43 | None | A-8 | B→A | D-15 | 590 | 8.1 | 0.42 | 2.0 | 400 | 4.3 | 0.34 | 0.6 | 0.29 | Comp. |
| SC-44 | None | A-8 | B→A | PEDOT | 690 | 4.6 | 0.58 | 1.8 | 380 | 3.6 | 0.43 | 0.6 | 0.32 | Comp. |
| SC-45 | C-1 | A-7 | B→A | D-15 | 620 | 8.1 | 0.41 | 2.1 | 450 | 5.1 | 0.34 | 0.8 | 0.38 | Comp. |
| SC-46 | C-1 | A-7 | B→A | PEDOT | 710 | 4.6 | 0.59 | 1.9 | 420 | 4.0 | 0.39 | 0.7 | 0.34 | Comp. |
| SC-47 | C-1 | A-8 | B→A | D-15 | 630 | 7.9 | 0.44 | 2.2 | 430 | 4.9 | 0.30 | 0.6 | 0.29 | Comp. |
| SC-48 | C-1 | A-8 | B→A | PEDOT | 720 | 4.5 | 0.56 | 1.8 | 460 | 3.9 | 0.40 | 0.7 | 0.40 | Comp. |
| SC-49 | C-2 | A-7 | B→A | D-15 | 450 | 3.0 | 0.39 | 0.5 | 460 | 1.9 | 0.39 | 0.3 | 0.65 | Comp. |
| SC-50 | C-2 | A-7 | B→A | PEDOT | 580 | 2.4 | 0.58 | 0.8 | 570 | 1.7 | 0.58 | 0.6 | 0.70 | Comp. |
| SC-51 | C-2 | A-8 | B→A | D-15 | 490 | 2.8 | 0.40 | 0.5 | 480 | 1.9 | 0.40 | 0.4 | 0.66 | Comp. |
| SC-52 | C-2 | A-8 | B→A | PEDOT | 590 | 3.1 | 0.56 | 1.0 | 570 | 1.8 | 0.56 | 0.6 | 0.56 | Comp. |

From Tables 1 and 2, it is found that the photoelectric conversion element in which the compound of the present invention was absorbed to the semiconductor exhibits high photoelectric conversion efficiency and excellent durability for light exposure, comparing to the photoelectric conversion element without absorbing the compound before dye absorption, or the case of absorbing C-1 (compound out of the present invention) which has methyl group at R₁ in Formula (1), or the case of absorbing C-2 (compound out of the present invention).

What is claimed is:

1. A photoelectric conversion element comprising a substrate provided thereon a first electrode, a photoelectric conversion layer having a semiconductor and a sensitizing dye, a charge transporting layer and a second electrode, wherein the photoelectric conversion layer comprising a compound represented by Formula (1),
R₁—X—R₂—B, Formula (1)
wherein R₁ represents C(R₃)(R₄)(R₅), R₃, R₄, and R₅ respectively represents a hydrogen atom, a methyl group or an ethyl group, provided that R₃, R₄, and R₅ are not simultaneously a hydrogen atom, X represents a substituted or non-substituted cyclohexane ring, a substituted or non-substituted benzene ring, or a substituted or non-substituted pyrimidine ring, R₂ represents a methylene group, an ethylene group, or a single bond, B represents a carboxyl group, a sulfo group or a phosphono group.

2. The photoelectric conversion element of claim 1, wherein R₁ in Formula (1) represents t-butyl group, i-propyl group, or triethylmethyl group.

3. The photoelectric conversion element of claim 1, wherein X in Formula (1) represents a substituted or non-substituted cyclohexane ring.

4. The photoelectric conversion element of claim 1, wherein R₂ in Formula (1) represents a single bond.

5. The photoelectric conversion element of claim 1, wherein B in Formula (1) represents a carboxyl group.

6. The photoelectric conversion element of claim 1, wherein the semiconductor represents titan oxide.

7. The photoelectric conversion element of claim 1, wherein the photoelectric conversion layer is formed on the semiconductor by absorbing a dye after absorbing the compound.

8. The photoelectric conversion element of claim 1, wherein the charge transporting layer comprises a p-type compound semiconductor.

9. A solar cell comprising the photoelectric conversion element of claim 1.
